(19) United States
(12) Patent Application Publication
(10) Pub. No.: US 2026/0156803 A1
(43) Pub. Date: Jun. 4, 2026

(54) SEMICONDUCTOR DEVICES AND MANUFACTURING METHODS THEREOF, AND MEMORY SYSTEMS

(71) Applicant: Yangtze Memory Technologies Co., Ltd., Wuhan (CN)

(72) Inventors: Cheng Zhang, Wuhan (CN); Sen Yao, Wuhan (CN); Wenxiu Huang, Wuhan (CN); Ping Yin, Wuhan (CN); Guangcan Ran, Wuhan (CN); Meng Wang, Wuhan (CN)

(21) Appl. No.: 19/051,068

(22) Filed: Feb. 11, 2025

(30) Foreign Application Priority Data
Dec. 2, 2024 (CN) 202411756559.7

(51) Int. Cl. H10B 12/00; H10D 1/00; H10D 1/68

(52) U.S. Cl. CPC H10B 12/315; H10B 12/033; H10D 1/042; H10D 1/716

(57) ABSTRACT

The examples of the present disclosure provide a semiconductor device and a manufacturing method thereof, and a memory system. The semiconductor device comprises a first electrode and a first insulating layer. The first electrode extends along a first direction and comprises a first end surface, a second end surface, and a sidewall. The first end surface and the second end surface are oppositely arranged in the first direction, and the sidewall connects the first end surface with the second end surface. The first insulating layer surrounds at least a portion of a sidewall of a first end portion of the first electrode and is located on a side of the first end surface away from the second end surface.

### CROSS-REFERENCE TO RELATED APPLICATIONS

This application claims priority to and the benefit of Chinese Patent Application 202411756559.7, filed on Dec. 2, 2024, which is hereby incorporated by reference in its entirety.

### TECHNICAL FIELD

The present disclosure relates to the field of semiconductor technology, and in particular, to semiconductor devices, memory systems, and manufacturing method methods of the semiconductor devices.

### BACKGROUND

The semiconductor device may be applied to a memory, such as a dynamic random access memory (DRAM). DRAM is widely applied to memories of electronic devices such as computers and mobile phones due to its characteristics such as simple structure, large capacity, high density, low power consumption, high speed and the like.

### BRIEF DESCRIPTION OF DRAWINGS

Other features, objectives, and advantages of the present disclosure will become more apparent according to the detailed description of non-limiting examples made with reference to the following drawings.

FIG. 1 is a schematic cross-sectional view of a semiconductor device provided in an example of the present disclosure;

FIG. 2 is a schematic cross-sectional view of a semiconductor device taken along another plane provided in an example of the present disclosure;

FIG. 3 is a schematic flowchart of a manufacturing method of a semiconductor device provided in an example of the present disclosure;

FIG. 4A to FIG. 4P are schematic cross-sectional views of a semiconductor device in a manufacturing process provided in an example of the present disclosure;

FIG. 5 is a schematic block diagram of a system having a memory system provided in an example of the present disclosure; and

FIG. 6A and FIG. 6B are schematic block diagrams of a memory system provided in an example of the present disclosure.

### DETAILED DESCRIPTION

With the development of technology nodes, the improvement of electrical performance of semiconductor devices and the reduction of process difficulty have encountered bottlenecks.

In order to have a better understanding of the present disclosure, various aspects of the present disclosure will be described in more detail with reference to the accompanying drawings. It should be understood that these detailed descriptions are merely descriptions of implementations of the present disclosure, and are not intended to limit the scope of the present disclosure in any way. Throughout the specification, the same reference numbers refer to the same elements. The expression “and/or” comprises any and all combinations of one or more of the associated listed items.

It should be noted that in this specification, the expressions of the first, second, third, etc. are merely used to distinguish one feature from another, and do not represent any limitation on the feature, and in particular, do not represent any order. Thus, the first electrode discussed in this disclosure may also be referred to as a second electrode and vice versa without departing from the teachings of the present disclosure.

In the drawings, the thickness, size, and shape of the components have been slightly adjusted for ease of illustration. The drawings are merely examples and are not drawn to scale. As used herein, the terms “approximately”, “about”, and the like are used as terms to denote an approximation, and are not used as terms of degree, and are intended to illustrate inherent deviations in measured values or calculated values to be recognized by those of ordinary skill in the art.

It should also be understood that expressions such as “comprise”, “comprising”, “having”, “include”, and/or “including”, and the like, are open and not closed expressions in this specification that indicate the presence of stated features, elements, and/or components, but do not preclude the presence of one or more other features, elements, components, and/or combinations thereof. Furthermore, when an expression such as “at least one of” appears after the list of listed features, it refers to the entire list of features rather than just referring to an individual element in the list. Furthermore, when describing implementations of the present disclosure, the term “may” is used to indicate “one or more implementations of the present disclosure”. Also, the term “exemplary” is intended to refer to an example or illustration.

Unless otherwise defined, all terms (including engineering terms and scientific terms) used herein have the same meaning as is commonly understood by those of ordinary skill in the art to which this disclosure pertains. It should also be understood that unless stated explicitly in the present disclosure, words defined in commonly used dictionaries should be interpreted as having a meaning that is consistent with their meaning in the context of the related art, and should not be interpreted in an idealized or overly formal sense.

It should be noted that, in the case of no conflict, implementations and features in the implementations of the present disclosure may be combined with each other. In addition, unless expressly defined or contradicted with context, the specific operations included in the method described in this disclosure are not necessarily limited to the recited order, but may be performed in any order or in parallel.

Furthermore, the term “connected” or “coupled”, when used in the present disclosure, may represent direct or indirect contact between the corresponding components, unless otherwise defined or otherwise derived from the context.

Hereinafter, the present disclosure will be described in detail with reference to the accompanying drawings and the examples.

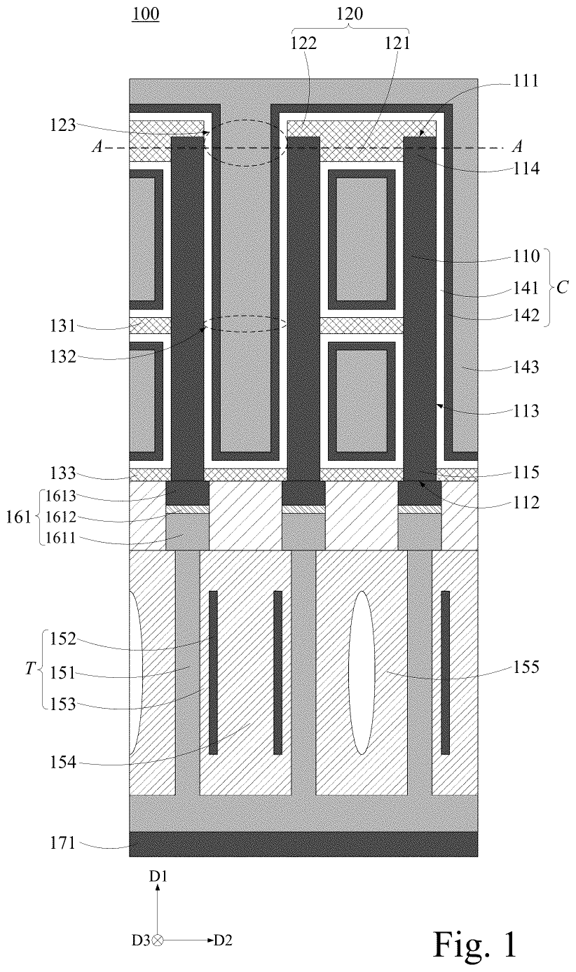

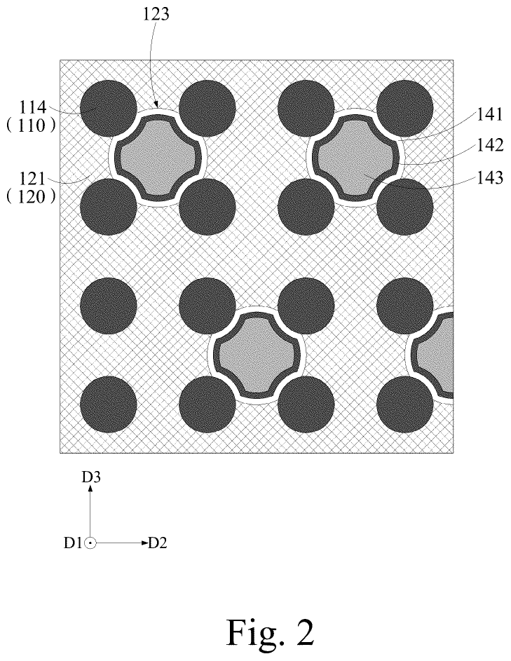

Some examples of the present disclosure provide a semiconductor device. FIG. 1 is a schematic cross-sectional view of a semiconductor device provided in an example of the present disclosure. FIG. 2 is a schematic cross-sectional view of a semiconductor device taken along another plane provided in an example of the present disclosure. For example, FIG. 2 may be a schematic cross-sectional view taken along a plane where the line AA shown in FIG. 1 is located.

It should be noted that the D1 direction (corresponding to the first direction), the D2 direction, and the D3 direction in the following figures show the spatial relationship of the components in the semiconductor device. For example, the D1 direction may be an extension direction of the first electrode, and the D2 direction and the D3 direction may be two directions intersecting with (e.g., perpendicular to) each other in a plane intersecting with (e.g., perpendicular to) the extension direction. The same concept will be applied throughout the present disclosure to describe the spatial relationship of the components in the semiconductor device.

As shown in FIG. 1, the semiconductor device 100 may comprise a first electrode 110 and a first insulating layer 120. The first electrode 110 may comprise a first end surface 111, a second end surface 112, and a sidewall 113. The first end surface 111 and the second end surface 112 are oppositely arranged in the D1 direction, and the sidewall 113 connects the first end surface 111 and the second end surface 112. The first insulating layer 120 may surround at least a portion of a sidewall of a first end portion 114 of the first electrode 110 and be located on a side of the first end surface 111 away from the second end surface 112. By having the first insulating layer 120 partially located on a side of the first end surface 111 away from the second end surface 112, it also helps to improve the supporting performance for the first electrode 110. Especially for the first electrode 110 having a larger size in the D1 direction, the first insulating layer 120 can improve the structural stability of the first electrode 110, thereby improving the yield of the semiconductor device 100.

In some implementations, the first electrode 110 may be a pillar structure. Optionally, the pillar structure may have an inclination angle. For example, the first electrode 110 may be a cylindrical structure having an inclination angle. The first end surface 111 and the second end surface 112 may be substantially circular. The sidewall 113 may be substantially cylindrical. The first electrode 110 may serve as a plate of the capacitor C. Such a capacitor C may be referred to as a pillar capacitor.

In some implementations, the first end 114 of the first electrode 110 may be a portion of the first electrode 110 comprising the first end surface 111 and a portion of the sidewall 113. The sidewall of the first end portion 114 may surround the first end surface 111, and a size of the sidewall of the first end portion 114 in the D1 direction is smaller than a size of the sidewall 113 of the first electrode 110 in the D1 direction. A second end portion 115 of the first electrode 110 may be a portion of the first electrode 110 comprising the second end surface 112 and a portion of the sidewall 113. A sidewall of the second end portion 115 may surround the second end surface 112, and a size of the sidewall of the second end portion 115 in the D1 direction is smaller than the size of the sidewall 113 of the first electrode 110 in the D1 direction.

In some implementations, a size of the first electrode 110 in the D1 direction may be greater than 950 nm. For example, the size of the first electrode 110 in the D1 direction may range from 1100 nm to 1200 nm. For example, the size of the first electrode 110 in the D1 direction may be 1000 nm, 1050 nm, 1100 nm, 1150 nm, and 1200 nm, etc. The size of the first electrode 110 in the D1 direction is related to the ability of the capacitor C to store charges. For example, in case that the first electrode 110 has a preset area in a plane perpendicular to the D1 direction, the larger the size of the first electrode 110 in the D1 direction, the stronger the ability of the capacitor C to store charges.

In some implementations, a ratio of the size of the first electrode 110 in the D1 direction to a size of the first electrode 110 in a direction (for example, a D2 direction or a D3 direction) intersecting with the D1 direction is greater than 33. For example, the ratio may be greater than 40. For example, the ratio may be 35, 40, 45, and 50, etc. The high performance of an etching apparatus may be required when the ratio is higher for the first electrode 110. In the semiconductor device 100, since the first insulating layer 120 having the portion on the side of the first end surface 111 away from the second end surface 112 is formed after the first electrode 110 is formed, the requirement on the performance of the etching apparatus can be reduced, which helps to reduce the cost.

In some implementations, the material of the first electrode 110 may comprise one or more of titanium, titanium nitride, tantalum, tantalum nitride, tungsten, molybdenum, copper, aluminum, ruthenium, a doped semiconductor (e.g., doped polysilicon), or any other suitable conductive material. For example, the first electrode 110 may be composed of a single material (e.g., titanium nitride).

In some implementations, as shown in FIG. 2, a plurality of first electrodes 110 are arranged at intervals. For example, from the D1 direction, the plurality of first electrodes 110 are arranged in an array. There is a spacing distance between adjacent first electrodes 110 in the D2 direction. There is a spacing distance between adjacent first electrodes 110 in the D3 direction.

In some implementations, the first insulating layer 120 may extend along the D2 direction and the D3 direction. The sizes of the first insulating layer 120 in the D2 direction and the D3 direction may be greater than the size of the first insulating layer 120 in the D1 direction. For example, the first insulating layer 120 may be a layered structure having a thickness in the D1 direction. In addition, the size of the first insulating layer 120 in the D1 direction may be smaller than the size of the first electrode 110 in the D1 direction.

In some implementations, the first insulating layer 120 may comprise a first extension portion 121 and a second extension portion 122. The first extension portion 121 may surround at least a portion of the sidewall of the first end portion 114. The second extension portion 122 may be located on the side of the first end surface 111 away from the second end surface 112. The first extension portion 121 and the second extension portion 122 are coplanar on a surface away from the first end surface 111 in the D1 direction. For example, when the semiconductor device 100 is in the placing position shown in FIG. 1, an upper surface of the first extension portion 121 is higher than the first end surface 111, and a lower surface of the first extension portion 121 is lower than the first end surface 111. The second extension portion 122 is located above the first end surface 111. The upper surfaces of the first extension portion 121 and the second extension portion 122 are substantially flush.

It should be noted that the first extension portion 121 and the second extension portion 122 are to further illustrate the position relationship between the respective portions of the first insulating layer 120 and the first electrode 110. In some practical applications, the first extension portion 121 and the second extension portion 122 may be an integral structure without an interface therebetween.

In some implementations, the first insulating layer 120 is in contact with at least a portion of the sidewall of the first end portion 114 and is in contact with the first end surface 111. For example, the first extension portion 121 may be in contact with at least a portion of the sidewall of the first end portion 114, and the second extension portion 122 may be in contact with the first end portion 111.

In some implementations, in a case where the plurality of first electrodes 110 are arranged at intervals, a portion of the first insulating layer 120 (for example, the second extension portion 122) may be located on (for example, in contact with) a side of the first end surface 111 of each first electrode 110 away from the second end surface 112.

In some implementations, as shown in FIG. 1 and FIG. 2, when viewing from the D1 direction, the first insulating layer 120 may have one or more first hollow portions 123. For example, the first hollow portion 123 may be substantially circular, elliptical, rectangular, or other irregular shapes. The single first hollow portion 123 may be located between adjacent first electrodes 110. For example, when viewing from the D1 direction, four first electrodes 110 may surround one first hollow portion 123. In a case where the first hollow portion 123 exposes the first electrode 110, the first insulating layer 120 (e.g., the first extension portion 121) may surround a portion of the sidewall of the first end portion 114. In a case where the first hollow portion 123 does not expose the first electrode 110 (for example, the first hollow portion has a smaller size in a plane perpendicular to the D1 direction), the first insulating layer 120 (for example, the first extension portion 121) may surround the entire sidewall (not shown) of the first end portion 114.

It should be noted that the first hollow portion 123 is intended to further illustrate the morphology of the first insulating layer 120, rather than to indicate that the first insulating layer 120 is empty at the position of the first hollow portion 123. In some practical applications, the capacitor dielectric layer 141, the second electrode 142 and the conductive layer 143 are located at the position of the first hollow portion 123. The capacitor dielectric layer 141, the second electrode 142, and the conductive layer 143 will be described below in detail.

In some implementations, the material of the first insulating layer 120 may comprise one or more of silicon nitride, silicon carbonitride, silicon boron nitride, and any other suitable insulating material.

In some implementations, as shown in FIG. 1, the semiconductor device 100 may further comprise a second insulating layer 131. There is a spacing distance between the second insulating layer 131 and the first insulating layer 120 in the D1 direction. The second insulating layer 131 may extend along the D2 direction and the D3 direction. The sizes of the second insulating layer 131 in the D2 direction and the D3 direction may be greater than the size of the second insulating layer 131 in the D1 direction. For example, the second insulating layer 131 may be a layered structure having a substantially uniform thickness in the D1 direction. In addition, the size of the second insulating layer 131 in the D1 direction may be smaller than the size of the first electrode 110 in the D1 direction.

In some implementations, when viewing from the D1 direction, the second insulating layer 131 may have one or more second hollow portions 132. For example, the second hollow portion 132 may be substantially circular, elliptical, rectangular, or other irregular shapes. A single second hollow portion 132 may be located between adjacent first electrodes 110. As an example, when viewing from the D1 direction, the projection of the first hollow portion 123 may substantially overlap with the projection of the second hollow portion 132. In a case where the second hollow portion 132 exposes the first electrode 110, the second insulating layer 131 may surround a portion of the sidewall of a middle portion of the first electrode 110. In a case where the second hollow portion 132 does not expose the first electrode 110 (for example, the second hollow portion has a smaller size in a plane perpendicular to the D1 direction), the second insulating layer 131 may surround the entire sidewall of the middle portion of the first electrode 110.

It should be noted that, similarly, the second hollow portion 132 is intended to further illustrate the morphology of the second insulating layer 131, rather than to indicate that the second insulating layer 131 is empty at the position of the second hollow portion 132. In some practical applications, the capacitor dielectric layer 141, the second electrode 142 and the conductive layer 143 are located at the position of the second hollow portion 132.

In some implementations, there may be one or more second insulating layers 131. When there is a plurality of second insulating layers 131 (not shown), the plurality of second insulating layers 131 may be arranged at intervals in the D1 direction. For example, the plurality of second insulating layers 131 may be disposed substantially parallel to each other. The spacing distances between adjacent second insulating layers 131 may be the same or different. The sizes of the respective second insulating layers 131 and the first insulating layers 120 in the D1 direction may be the same as or different from each other. Increasing the number of the second insulating layer 131 can further improve the structural stability of the first electrode 110.

In some implementations, the material of the second insulating layer 131 may comprise one or more of silicon nitride, silicon carbonitride, silicon boron nitride, and any other suitable insulating material.

In some implementations, as shown in FIG. 1, the semiconductor device 100 may further comprise a third insulating layer 133. There is the spacing distance between the third insulating layer 133 and the (e.g., closest) second insulating layer 131 in the D1 direction. For example, when the semiconductor device 100 is in the placing position shown in FIG. 1, a lower surface of the third insulating layer 133 is substantially flush with the second end surface 112. In addition, the third insulating layer 133 may extend along the D2 direction and the D3 direction. The sizes of the third insulating layer 133 in the D2 direction and the D3 direction may be greater than the size of the third insulating layer 133 in the D1 direction. For example, the third insulating layer 133 may be a layered structure having a substantially uniform thickness in the D1 direction. The size of the third insulating layer 133 in the D1 direction may be smaller than the size of the first electrode 110 in the D1 direction.

In some implementations, the third insulating layer 133 may surround the entire sidewall of the second end portion 115 of the first electrode 110. The third insulating layer 133 not only can support the first electrode 110, but also serve as an etching stop layer in the process of forming the capacitor C.

In some implementations, the material of the third insulating layer 133 may comprise one or more of silicon nitride, silicon carbonitride, silicon boron nitride, and any other suitable insulating material.

In some implementations, as shown in FIG. 1, the semiconductor device 100 may further comprise a capacitor dielectric layer 141 and a second electrode 142. A portion of the capacitor dielectric layer 141 may be located on a side of the first electrode 110 in a direction intersecting with the D1 direction, and a portion of the capacitor dielectric layer 141 may be located on two opposite sides of the first insulating layer 120 in the D1 direction. Optionally, the portion of the capacitor dielectric layer 141 may also be located on two opposite sides of the second insulating layer 131 in the D1 direction, and the portion of the capacitor dielectric layer 141 may also be located on a side of the third insulating layer 133 toward the second insulating layer 131. The second electrode 142 may be located on a side of the capacitor dielectric layer 141 away from the first electrode 110 and the first insulating layer 120. Optionally, the second electrode 142 may be located on a side of the capacitor dielectric layer 141 away from the second insulating layer 131 and the third insulating layer 133. For example, the first electrode 110 may be in contact with the capacitor dielectric layer 141. In other words, a portion of the second electrode 142 may be located on a side of the first electrode 110 in a direction intersecting with the D1 direction, and a portion of the second electrode 142 may be located on two opposite sides of the first insulating layer 120 in the D1 direction. A portion of the capacitor dielectric layer 141 may be located between the first electrode 110 and the second electrode 142. The second electrode 142 may be a layered structure. The second electrode 142 may act as another plate of the capacitor C.

In some implementations, in a case where the plurality of first electrodes 110 are arranged at intervals, the capacitor dielectric layers 141 corresponding to the respective first electrodes 110 may be connected to each other and may be of an integral structure. The second electrodes 142 corresponding to the respective first electrodes 110 may also be connected to each other and may be of an integral structure.

In some implementations, the material of the capacitor dielectric layer 141 may comprise one or more of silicon oxide, silicon nitride, silicon oxynitride, a high dielectric constant material, or any other suitable insulating material. The high dielectric constant material may comprise, but is not limited to, aluminum oxide, titanium oxide, tantalum oxide, hafnium oxide, zirconium oxide, and the like. The material of the second electrode 142 may comprise one or more of titanium, titanium nitride, tantalum, tantalum nitride, tungsten, molybdenum, copper, aluminum, ruthenium, doped semiconductors, or any other suitable conductive material. For example, the material of the second electrode 142 may be titanium nitride.

In some implementations, as shown in FIG. 1, the semiconductor device 100 may further comprise a conductive layer 143. The conductive layer 143 may be located on a side of the second electrode 142 away from the capacitor dielectric layer 141. The conductive layer 143 may be configured to provide a relatively flat surface perpendicular to the D1 direction. For example, the material of the conductive layer 143 may comprise silicon germanium.

In some implementations, the portion of the capacitor dielectric layer 141 and the portion of the second electrode 142 may pass through the first insulating layer 120 and the second insulating layer 131 in the D1 direction. For example, in a case where the first insulating layer 120 has the first hollow portion 123 and the second insulating layer 131 has the second hollow portion 132, the portion of the capacitor dielectric layer 141 and the portion of the second electrode 142 pass through the first insulating layer 120 and the second insulating layer 131 at where the first hollow portion 123 and the second hollow portion 132 are located. Optionally, the conductive layer 143 may also pass through the first insulating layer 120 and the second insulating layer 131 in the D1 direction at where the first hollow portion 123 and the second hollow portion 132 are located.

In some implementations, as shown in FIG. 1, the semiconductor device 100 may further comprise a semiconductor body 151. The semiconductor body 151 may extend along the D1 direction and may be located on a side of the first electrode 110 in the D1 direction and away from the first end surface 111. For example, the size of the semiconductor body 151 in the D1 direction may be larger than the size of the semiconductor body 151 in the D2 direction and may be larger than the size of the semiconductor body 151 in the D3 direction. The semiconductor body 151 as a whole may be a pillar structure (e.g., a quadrangular prism) extending along the D1 direction. For example, the semiconductor body 151 may serve as a channel and an active region of the transistor T.

In some implementations, the material of the semiconductor body 151 may comprise silicon, germanium, silicon germanium, silicon carbide, gallium nitride, or any other suitable semiconductor material. For example, the material of the semiconductor body 151 may be silicon (e.g., monocrystalline silicon).

In some implementations, the plurality of semiconductor bodies 151 may be arranged at intervals. For example, when viewing from the D1 direction, the plurality of semiconductor bodies 151 are arranged in an array. There is a spacing distance between adjacent semiconductor bodies 151 in the D2 direction. There is a spacing distance between adjacent semiconductor bodies 151 in the D3 direction. For example, the respective end portions of semiconductor bodies 151 of a row arranged in the D2 direction away from the first electrodes 110 are connected to each other.

In some implementations, as shown in FIG. 1, the semiconductor device 100 may further comprise a gate structure 152. The gate structure 152 may be located on a side of the semiconductor body 151 in a direction intersecting with the D1 direction. The size of the gate structure 152 in the D1 direction may be smaller than the size of the semiconductor body 151 in the D1 direction. In some examples, the gate structure 152 may be located on a single side of the semiconductor body 151 in the D2 direction. In another example, the gate structure 152 may be located on opposite sides of the semiconductor body 151 in the D2 direction. In yet other examples, the gate structure 152 may be located on opposite sides of the semiconductor body 151 in the D2 direction and on opposite sides of the semiconductor body 151 in the D3 direction. In addition, the gate structure 152 may also extend in the D3 direction. For example, the gate structure 152 may be connected to a column of semiconductor bodies 151 arranged along the D3 direction.

In some implementations, in a case where the gate structure 152 is located on a single side of the semiconductor body 151 in the D2 direction, as shown in FIG. 1, a shape of the gate structure 152 in a plane perpendicular to the D3 direction is a rectangle. The size of the rectangle in the D1 direction may be larger than the size of the rectangle in the D2 direction.

In some implementations, the material of the gate structure 152 may comprise one or more of titanium, titanium nitride, tantalum, tantalum nitride, tungsten, molybdenum, copper, aluminum, ruthenium, or any other suitable conductive material. For example, the material of the gate structure 152 may comprise tungsten and titanium nitride.

In some implementations, as shown in FIG. 1, the semiconductor device 100 may further comprise a gate dielectric layer 153. The gate dielectric layer 153 may be located between the gate structure 152 and the semiconductor body 151. The gate dielectric layer 153 may be in contact with the gate structure 152 and the semiconductor body 151. The material of the gate dielectric layer 153 may comprise one or more of silicon oxide, silicon nitride, silicon oxynitride, a high dielectric constant material, or any other suitable insulating material. The high dielectric constant material may comprise, but is not limited to, aluminum oxide, titanium oxide, tantalum oxide, hafnium oxide, zirconium oxide, and the like. For example, the material of the gate dielectric layer 153 may be silicon oxide.

The semiconductor body 151, the gate dielectric layer 153, and the gate structure 152 may constitute a transistor T. Two end portions of the semiconductor body 151 serve as two active regions of the transistor T, respectively. For example, when the semiconductor device 100 is in the placing position shown in FIG. 1, the upper end of the semiconductor body 151 may be the source of the transistor T, and the lower end portion of the semiconductor body 151 may be the drain of the transistor T. The channel and the active region of the transistor T are integrated in the vertical direction, which helps to save the planar area overhead of the transistor T.

In some implementations, as shown in FIG. 1, in a case where the gate structure 152 is located on a single side of the semiconductor body 151 in the D2 direction, the semiconductor device 100 may further comprise a first isolating structure 154. The first isolating structure 154 may extend along the D3 direction and may be located between adjacent semiconductor bodies 151 of one column (arranged in the D3 direction). The gate structure 152 and the gate dielectric layer 153 may be located between the first isolating structure 154 and the semiconductor body 151. The column of the semiconductor bodies 151, the gate structure 152, and the gate dielectric layer 153 are mirror-symmetrically arranged with respect to the first isolating structure 154.

In some implementations, the material of the first isolating structure 154 may comprise one or more of silicon oxide, silicon nitride, silicon oxynitride, or any other suitable insulating material. For example, the material of the first isolating structure 154 may comprise silicon oxide.

In some implementations, as shown in FIG. 1, in a case where the gate structure 152 is located on one side of the semiconductor body 151 in the D2 direction, the semiconductor device 100 may further comprise a second isolating structure 155. The second isolating structure 155 may extend along the D3 direction and may be located between adjacent semiconductor bodies 151 of one column (arranged in the D3 direction). The first isolating structure 154 and the second isolating structure 155 are alternately arranged in the D2 direction. The material of the second isolating structure 155 may comprise one or more of silicon oxide, silicon nitride, silicon oxynitride, or any other suitable insulating material.

In some implementations, an air gap may be provided in the second isolating structure 155. The air gap can provide shielding for adjacent transistors T.

In other implementations, the second isolating structure 155 may be replaced by a conductive structure and a dielectric layer (not shown). The conductive structure may extend along the D3 direction and may be located between adjacent semiconductor bodies 151 of one column (arranged in the D3 direction). The dielectric layer may be located between the conductive structure and the semiconductor body 151. For example, the dielectric layer is in contact with the conductive structure and the semiconductor body. The material of the conductive structure may comprise one or more of titanium, titanium nitride, tantalum, tantalum nitride, tungsten, molybdenum, copper, aluminum, ruthenium, doped semiconductors, or any other suitable conductive material. The material of the dielectric layer may comprise one or more of silicon oxide, silicon nitride, silicon oxynitride, high dielectric constant material, or any other suitable insulating material. The high dielectric constant material may comprise, but is not limited to, aluminum oxide, titanium oxide, tantalum oxide, hafnium oxide, zirconium oxide, and the like.

During operation of the semiconductor device 100, the conductive structure can provide shielding for the adjacent transistors T, thereby improving mutual interference between the adjacent transistors T. For example, the conductive structure may be configured to apply a ground voltage or a negative voltage during operation of the semiconductor device 100. The dielectric layer may function to electrically isolate the conductive structure and the semiconductor body 151.

In some implementations, as shown in FIG. 1, the semiconductor device 100 may further comprise a bit line structure 171. The bit line structure 171 may be located on a side of the semiconductor body 151 away from the first electrode 110 in the D1 direction, and may extend along the D2 direction. The bit line structure 171 may be connected (e.g., in contact) with semiconductor bodies 151 of a row (e.g., interconnected portions of respective end portions of semiconductor bodies 151 of the row) arranged in the D2 direction. In addition, the plurality of bit line structures 171 may be arranged at intervals in the D3 direction. The material of the bit line structure 171 may comprise one or more of titanium, titanium nitride, tantalum, tantalum nitride, tungsten, molybdenum, copper, aluminum, ruthenium, metal silicide, or any other suitable conductive material.

In some implementations, as shown in FIG. 1, the semiconductor device 100 may further comprise a connecting structure 161. The connecting structure 161 may extend along the D1 direction and may be connected to the second end surface 112 and the semiconductor body 151. For example, the connecting structure 161 may be substantially pillar structure. One of two opposite end surfaces of the connecting structure 161 in the D1 direction is in contact with the second end surface 112 of the first electrode 110, and the other one is in contact with an end surface of the semiconductor body 151 away from the bit line structure 171 in the D1 direction.

The connecting structure 161 may be configured to connect the capacitor C and the transistor T. Specifically, the first electrode 110 of the capacitor C may be electrically connected to, for example, the source of the transistor T through the connecting structure 161. The capacitor C and the transistor T may constitute a memory cell, which may be referred to as a DRAM memory cell, for example. The capacitor C may be configured to implement data storage, and the transistor T may be used as a switch for accessing data in the capacitor C.

In some implementations, as shown in FIG. 1, the connecting structure 161 may comprise a first connecting portion 1611, a metal silicide layer 1612, and a second connecting portion 1613 that are sequentially connected along the D1 direction. For example, the first connecting portion 1611 is in contact with the metal silicide layer 1612 and the semiconductor body 151. The metal silicide layer 1612 is in contact with the first connecting portion 1611 and the second connecting portion 1613. The second connecting portion 1613 is in contact with the metal silicide layer 1612 and the second end surface 112. The material of the first connecting portion 1611 may comprise a doped semiconductor, such as doped polysilicon. The material of the metal silicide layer 1612 may comprise one or more of titanium silicon, cobalt silicon, nickel silicon, platinum silicon, or other metal silicide materials. The material of the second connecting portion 1613 may comprise one or more of titanium, titanium nitride, tantalum, tantalum nitride, tungsten, molybdenum, copper, aluminum, ruthenium, or any other suitable conductive material. The connecting structure 161 is composed of the above composite material and may be configured to form an ohmic contact to reduce the contact resistance between the first electrode 110 and the semiconductor body 151.

In some implementations, the semiconductor device 100 may further comprise a peripheral circuit structure (not shown). The peripheral circuit structure may be located on a side of the semiconductor body 151 away from the first electrode 110 in the D1 direction. Alternatively, the peripheral circuit structure may be located on a side of the first electrode 110 away from the semiconductor body 151 in the D1 direction. In other words, the semiconductor body 151 (or the transistor T), the first electrode 110 (or the capacitor C), and the peripheral circuit structure may be stacked in the D1 direction.

In some implementations, the peripheral circuit structure may comprise a peripheral circuit of any suitable digital, analog, and/or mixed-signal for controlling operation of a memory cell array. For example, the peripheral circuit may comprise one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portion (e.g., sub-circuit) of the aforementioned functional circuit, or any active or passive component (e.g., transistor, diode, resistor, or capacitor) of the circuit.

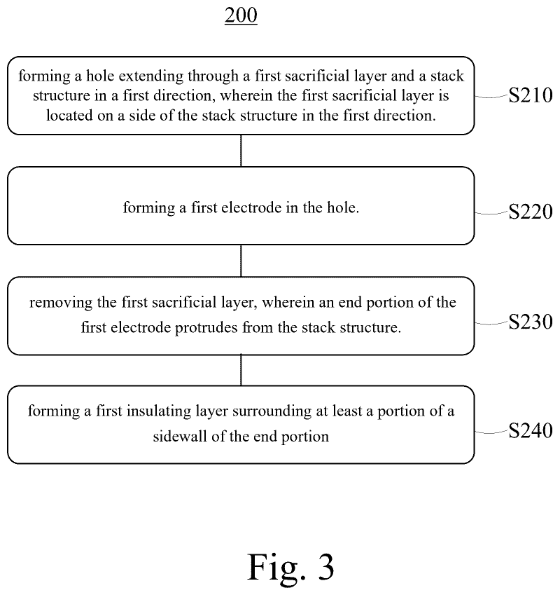

Some examples of the present disclosure further provide a manufacturing method of a semiconductor device. FIG. 3 is a schematic flowchart of a manufacturing method of a semiconductor device provided in an example of the present disclosure. As shown in FIG. 3, the manufacturing method 200 of the semiconductor device (hereinafter referred to as the manufacturing method 200) may comprise the following operations.

S210: forming a hole extending through a first sacrificial layer and a stack structure in a first direction, wherein the first sacrificial layer is located on a side of the stack structure in the first direction;

S220: forming a first electrode in the hole;

S230: removing the first sacrificial layer, wherein an end portion of the first electrode protrudes from the stack structure;

S240: forming a first insulating layer surrounding at least a portion of a sidewall of the end portion.

In the manufacturing method 200 provided in the example of the present disclosure, the first insulating layer is formed after the first electrode is formed, the operation of etching the first insulating layer may be omitted in the process of forming the first electrode, and the process difficulty of etching the stack structure can be reduced. In other words, providing that a preset (e.g., maximized) etching capability on the stack structure is maintained, the size of the first electrode in the first direction is increased.

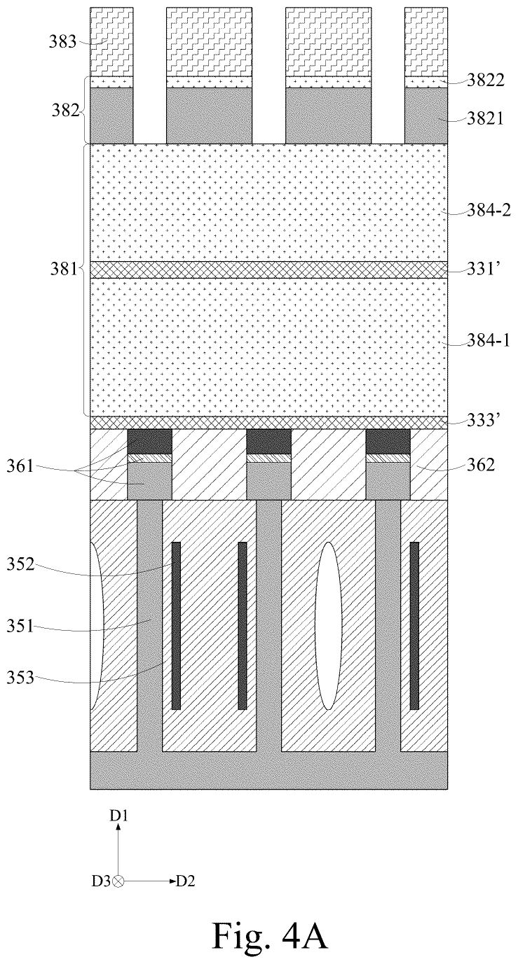

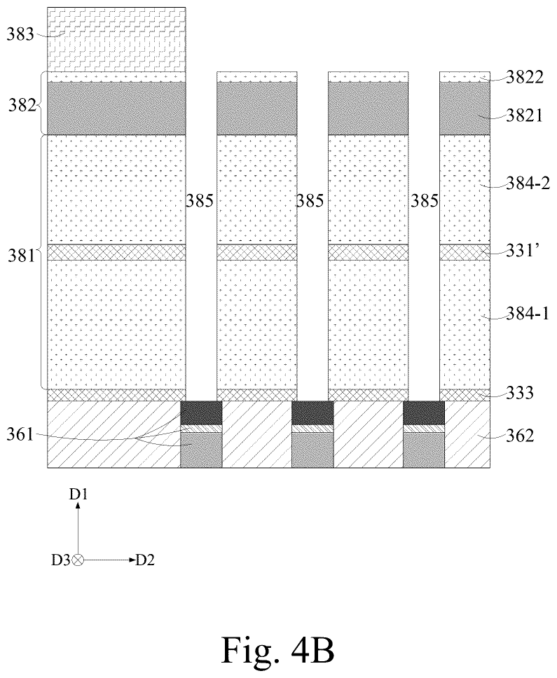

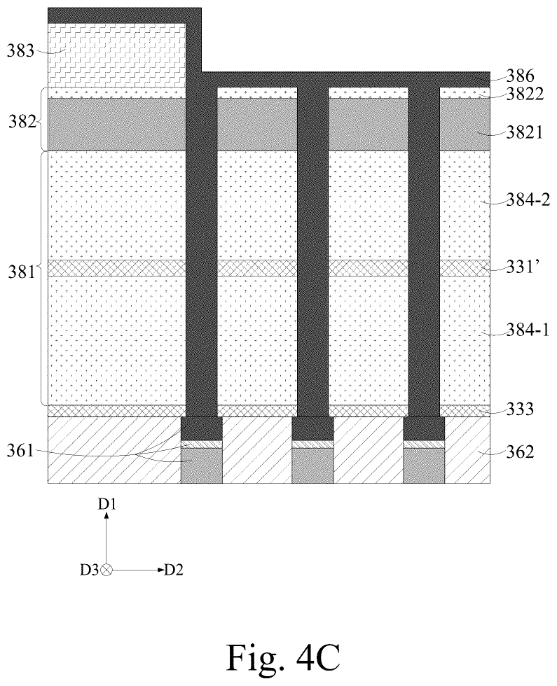

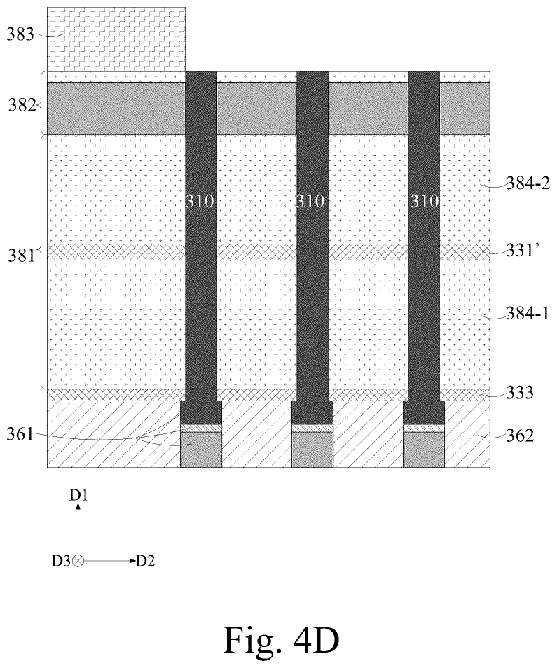

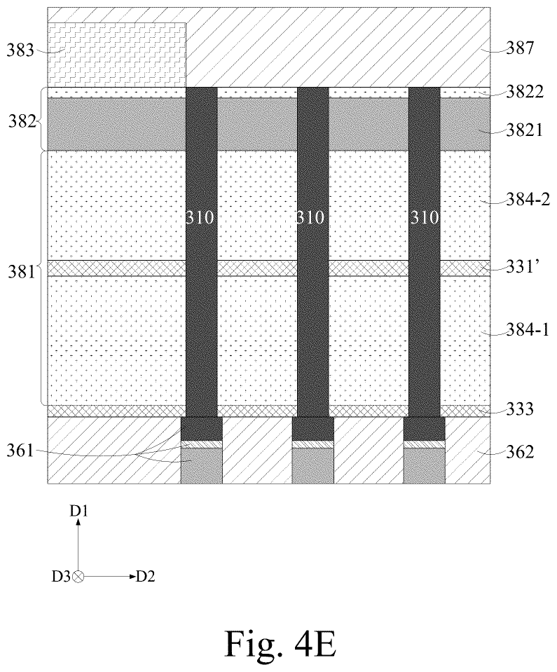

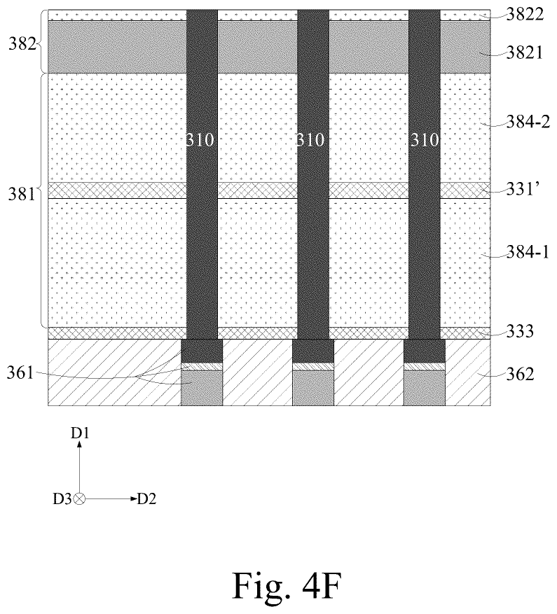

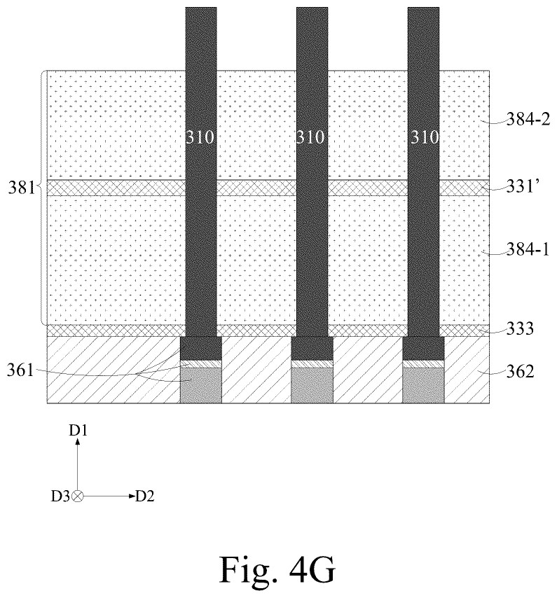

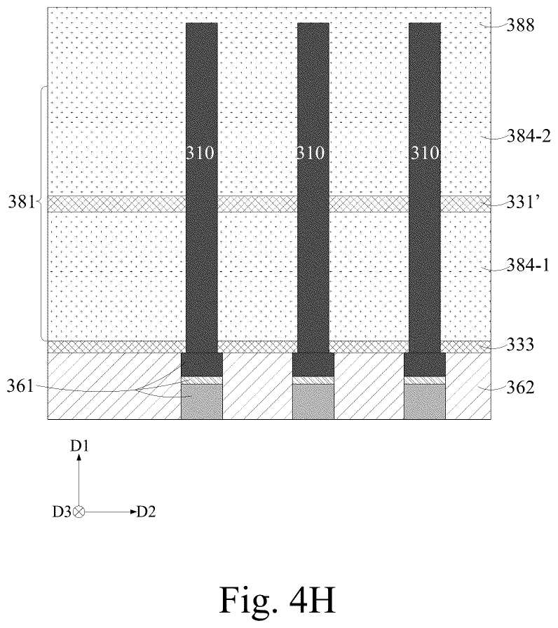

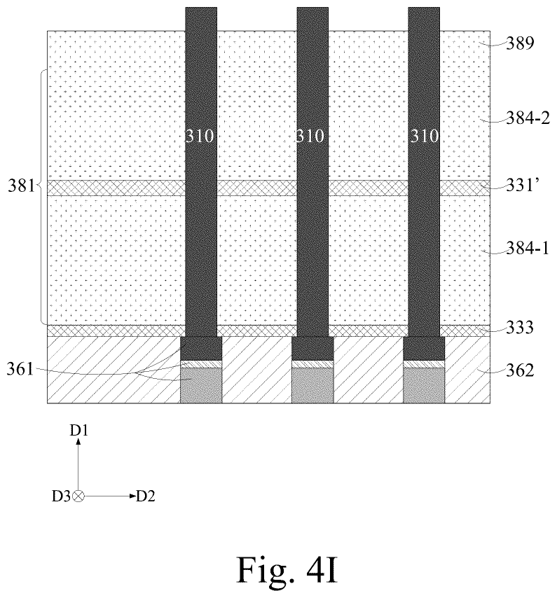

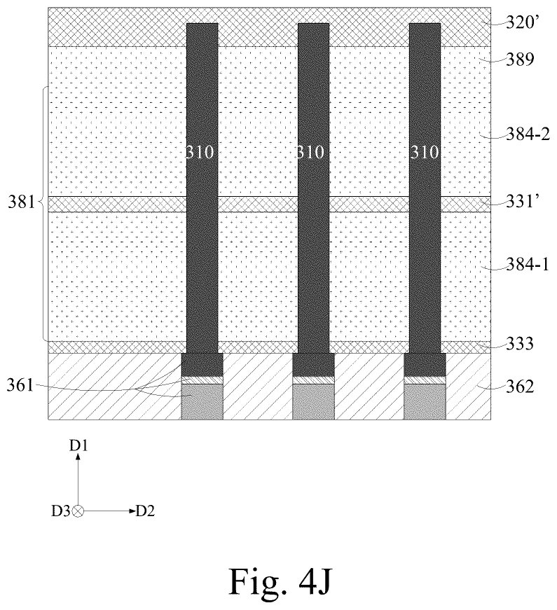

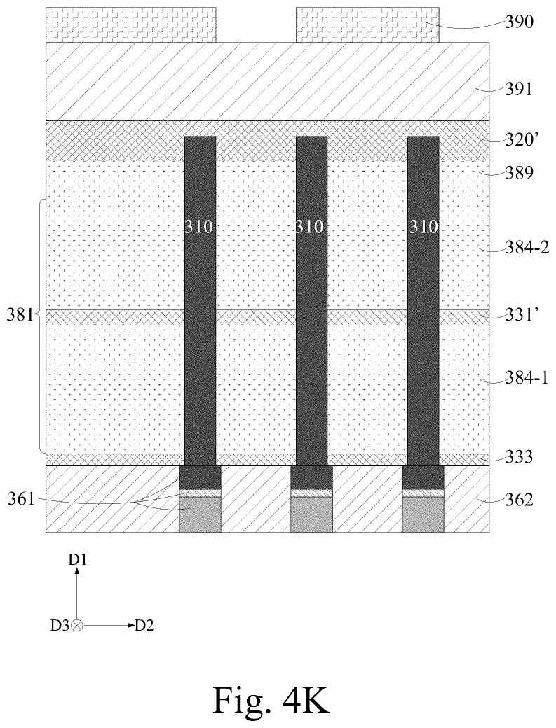

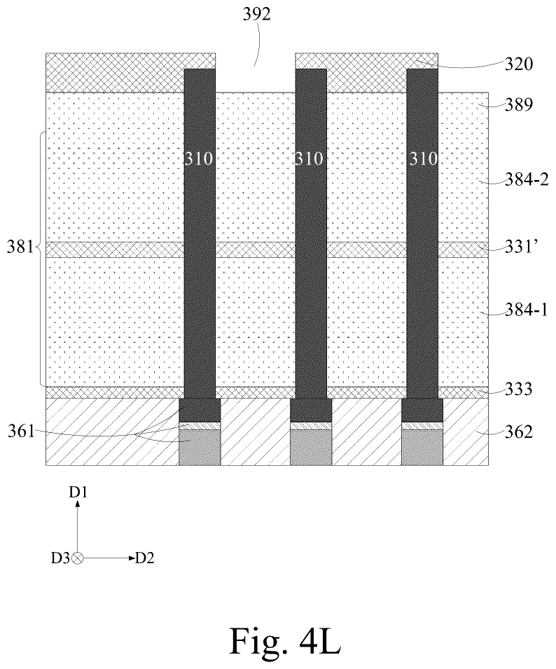

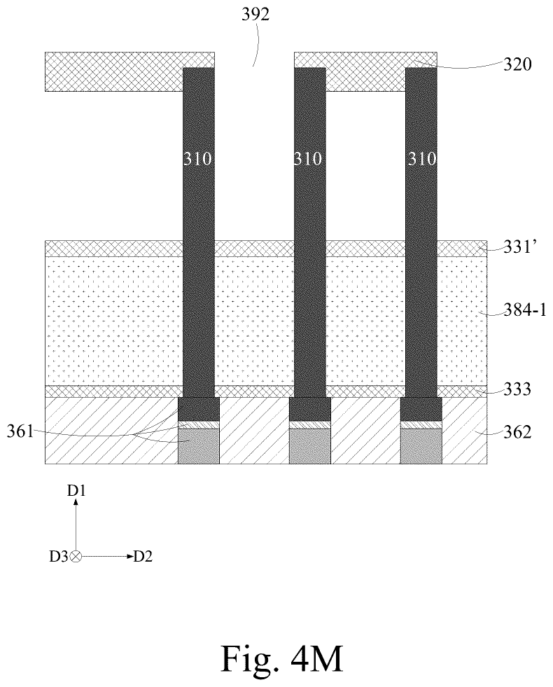

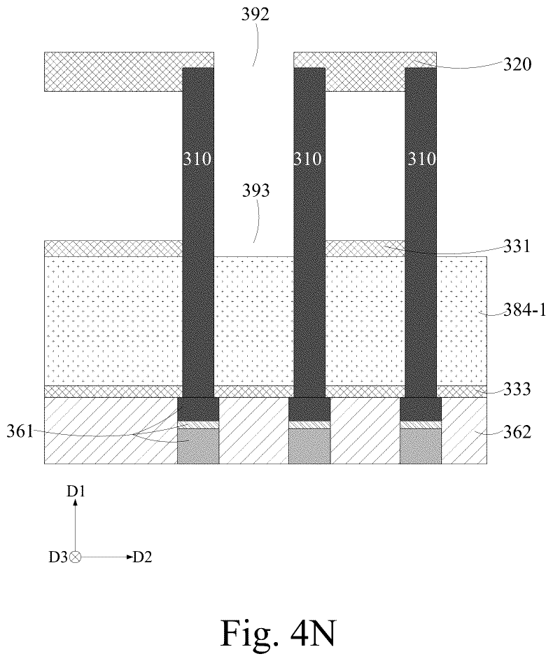

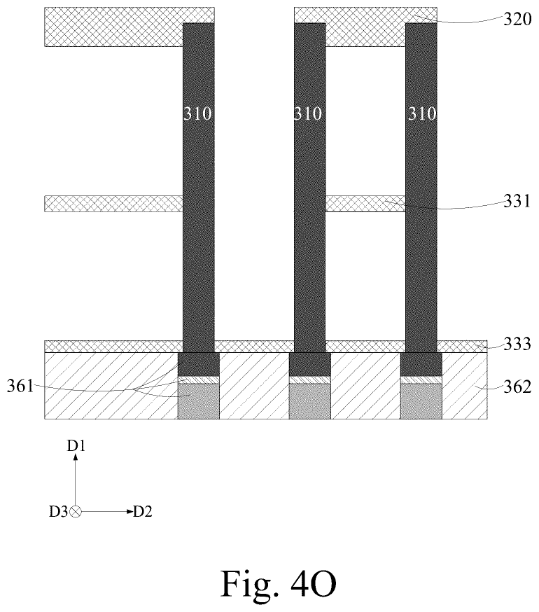

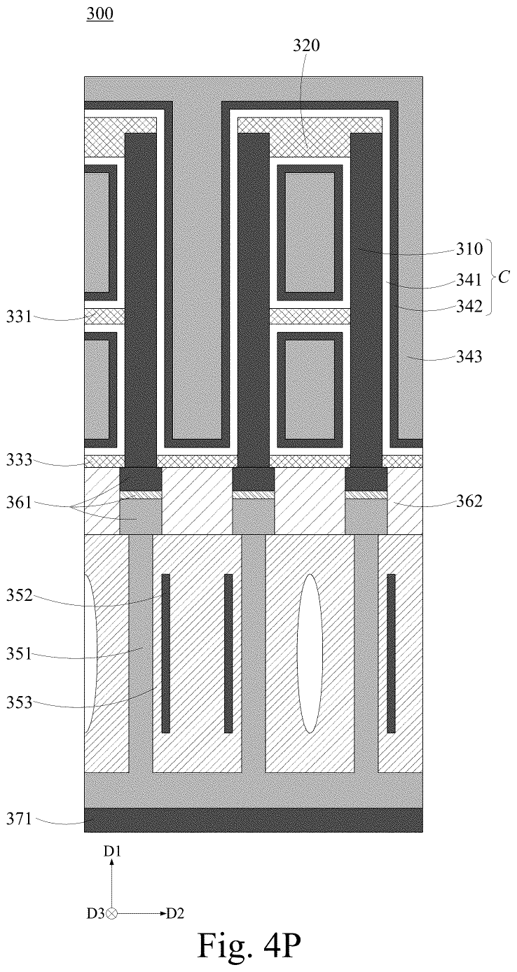

FIG. 4A to FIG. 4P are schematic cross-sectional views of the semiconductor device in the manufacturing process provided in an example of the present disclosure. In particular, FIG. 4A illustrates the intermediate structure after forming the patterned first sacrificial layer. FIG. 4B illustrates the intermediate structure after forming the hole. FIG. 4C illustrates the intermediate structure after depositing the conductive material. FIG. 4D illustrates the intermediate structure after forming the first electrode. FIG. 4E illustrates the intermediate structure after forming the cover layer. FIG. 4F illustrates the intermediate structure after removing the cover layer and the first mask layer. FIG. 4G illustrates the intermediate structure after removing the first sacrificial layer. FIG. 4H illustrates the intermediate structure after depositing the sacrificial material. FIG. 4I illustrates the intermediate structure after forming a third sacrificial layer. FIG. 4J illustrates the intermediate structure after forming an initial first insulating layer. FIG. 4K shows the intermediate structure after forming a patterned second mask layer and a patterned third mask layer. FIG. 4L illustrates the intermediate structure after forming a first opening. FIG. 4M illustrates the intermediate structure after removing portions of a second sacrificial layer. FIG. 4N illustrates the intermediate structure after forming the second opening. FIG. 4O illustrates the intermediate structure after removing another portion of the second sacrificial layer. FIG. 4P illustrates the semiconductor device 300 after forming a capacitor.

It should be noted that the “intermediate structure” as referred to in the present disclosure may be a structure formed during manufacture of the semiconductor device. In addition, in order to clearly show the components related to the above operations S210 to S240, the related components such as the semiconductor body, the gate structure and the gate dielectric layer are omitted in FIGS. 4B to 4O.

The manufacturing method 200 comprising the operations S210 to S240 is described below with reference to FIGS. 4A to 4P.

The method 200 begins at operation S210. As shown in FIG. 4A, for example, the stack structure 381 may be a composite layered structure extending along the D2 direction and the D3 direction and having a thickness in the D1 direction. The first sacrificial layer 382 may be formed on a side (e.g., a surface) of the stack structure 381 in the D1 direction by an oxidation process or a thin film deposition process such as chemical vapor deposition (CVD), physical vapor deposition (PVD), atomic layer deposition (ALD), or any combination thereof.

In some implementations, the stack structure 381 may comprise the second sacrificial layers 384-1, 384-2 and an initial second insulating layer 331′ that are alternately disposed in the D1 direction. For example, the second sacrificial layer 384-1, the initial second insulating layer 331', and the second sacrificial layer 384-2 are alternately disposed in the D1 direction. The second sacrificial layers 384-1, 384-2 and the initial second insulating layer 331′ may be formed by a thin film deposition process such as CVD, PVD, ALD, or any combination thereof. For example, the size of the initial second insulating layer 331′ in the D1 direction may be smaller than the size of the respective second sacrificial layers 384-1, 384-2 in the D1 direction.

It should be noted that the stack structure 381 shown in FIG. 4A having two second sacrificial layers 384-1, 384-2, and one initial second insulating layer 331′ is merely an example, and in other examples, the stack structure 381 may have a greater number (e.g., greater than 2) of the second sacrificial layers and a greater number (e.g., greater than 1) of the initial second insulating layers, and the numbers of the second sacrificial layer and the initial second insulating layer included in the stack structure is not specifically limited in the present disclosure. In addition, a surface of the second sacrificial layer in the D1 direction may serve as an outer surface of the stack structure in the D1 direction.

In some implementations, the material of the second sacrificial layers 384-1, 384-2 and the material of the initial second insulating layer 331′ may be different, such that the second sacrificial layers 384-1, 384-2 and the initial second insulating layer 331′ have different etching selectivity ratios with respect to the same etching material.

In some implementations, the material of the second sacrificial layer 384-1, 384-2 may include one or more of silicon oxide, silicon boron oxide, silicon phosphorus oxide, silicon boron phosphorus oxide, or any other suitable material that can be easily removed. The materials of the respective second sacrificial layers 384-1 and 384-2 may be the same or different, which is not limited in the present disclosure. The material of the initial second insulating layer 331′ may comprise one or more of silicon nitride, silicon boron nitride, silicon carbonitride, or any other suitable material.

In some implementations, the first sacrificial layer 382 may be a layered structure extending along the D2 direction and the D3 direction and having a thickness in the D1 direction. In some examples, the first sacrificial layer 382 may be a composite layered structure. The first sacrificial layer 382 may comprise a first sub-layer 3821 and a second sub-layer 3822. The first sub-layer 3821 and the second sub-layer 3822 may be sequentially formed on a side away from the stack structure 381 in the D1 direction. The first sub-layer 3821 may be in contact with the second sacrificial layer 384-2 in the stack structure 381. The size of the first sub-layer 3821 in the D1 direction may be greater than the size of the second sub-layer 3822 in the D1 direction. For example, the material of the first sub-layer 3821 may comprise silicon. The material of the second sub-layer 3822 may comprise silicon oxide. In other examples, the first sacrificial layer 382 may be composed of a single material, which is not specifically limited in the present disclosure.

In some implementations, at least a portion of the first sacrificial layer 382 is different from a material of the second sacrificial layers 384-1, 384-2 in the stack structure 381. In a case where the first sacrificial layer 382 may be a composite layered structure, the portion (e.g., the first sub-layer 3821) of the first sacrificial layer 382 being in contact with the second sacrificial layer 384-2 is different from the material of the second sacrificial layer 384-2.

In operation S210, as shown in FIGS. 4A and 4B, the pattern for forming the hole 385 may be transferred to the first sacrificial layer 382 by using the first mask layer 383. For example, the first mask layer 383 may be a hard mask or a photoresist. Next, the hole 385 extending through the stack structure 381 (e.g., the second sacrificial layer 384-2, the initial second insulating layer 331′, and the second sacrificial layer 384-1) along the D1 direction may be formed by using the patterned first sacrificial layer 382 and through an etching process (e.g., dry etching and/or wet etching). In a case where at least a portion of the first sacrificial layer 382 is different from the material of the second sacrificial layer 384-2 in the stack structure 381, at least the portion of the first sacrificial layer 382 may function as an etching mask during the formation of the hole 385. Optionally, at least a portion of the first mask layer 383 may be removed after forming the patterned first sacrificial layer 382.

After being processed by the above process, the hole 385 may extend through the first sacrificial layer 382 and the stack structure 381 along the D1 direction. The depth of the hole 385 may be determined based at least on the size of the stack structure 381 in the D1 direction and the size of the first sacrificial layer 382 in the D1 direction. In addition, the number of the holes 385 may be a plurality. The plurality of holes 385 may be arranged at intervals.

In some implementations, before performing the operation of forming the hole 385, the manufacturing method 200 may further comprise the following operations.

Illustratively, referring again to FIG. 4A, the semiconductor body 351 extending along the D1 direction may be formed. The stack structure 381 may be formed on a side of the semiconductor body 351 in the D1 direction. Further, the gate structure 352 may be formed on at least one side (e.g., one side in the D2 direction) of the semiconductor body 351 in a direction intersecting with the D1 direction. Further, a gate dielectric layer 353 may be formed between the gate structure 352 and the semiconductor body 351. The semiconductor body 351, the gate structure 352, and the gate dielectric layer 353 may be formed by any process method known in the art, and the above components have been described in detail above, which would not be repeated here.

Illustratively, as shown in FIG. 4A, an initial isolating layer (not shown) may be formed on a side of the semiconductor body 351 in the D1 direction by a thin film deposition process of CVD, PVD, ALD, or any combination thereof. The initial isolating layer may cover the end surface of the semiconductor body 351 in the D1 direction. For example, the initial isolating layer (not shown) may be a layered structure that extends along the D2 direction and the D3 direction and has a thickness in the D1 direction. Further, the connecting structure 361 extending through the initial isolating layer to the semiconductor body 351 may be formed, and the isolating layer 362 may be obtained. The material of the isolating layer 362 may comprise one or more of silicon oxide, silicon nitride, silicon oxynitride, or any other suitable insulating material.

Illustratively, as shown in FIG. 4A, an initial third insulating layer 333′ may be formed on a side of the connecting structure 361 away from the semiconductor body 351 in the D1 direction by a thin film deposition process such as CVD, PVD, ALD, or any combination thereof. The stack structure 381 may form on a side of the initial third insulating layer 333′ away from the connecting structure 361 in the D1 direction. For example, the second sacrificial layer 384-1 in the stack structure 381 is in contact with the initial third insulating layer 333′. The material of the initial third insulating layer 333′ may comprise one or more of silicon nitride, silicon carbonitride, silicon boron nitride, and any other suitable insulating material. For example, the material of the initial third insulating layer 333′ may be the same as the material of the initial second insulating layer 331′. In a case where the initial third insulating layer 333′ is formed, as shown in FIG. 4B, in the process of forming the hole 385, the hole 385 may extend through the initial third insulating layer 333′ to the connecting structure 361, and obtain the third insulating layer 333.

The manufacturing method 200 proceeds to operation S220. As shown in FIGS. 4B and 4C, the conductive material 386 may be deposited on top side of the intermediate structure shown in FIG. 4B by a thin film deposition process such as CVD, PVD, ALD, or any combination thereof. The conductive material 386 may be filled in the hole 385. Further, as shown in FIGS. 4C and 4D, a portion of the conductive material 386 outside the hole 385 may be removed, and the conductive material 386 remaining in the hole 385 may be the first electrode 310. It should be noted that the “top side” as referred to in the present disclosure refers to a side located at the top of the respective intermediate structure when the intermediate structure is in the placing position shown in the corresponding figure.

In some implementations, as shown in FIGS. 4D and 4E, a cover layer 387 may be formed on a top side of the intermediate structure shown in FIG. 4D by a spin coating process. The cover layer 387 may be used to provide a flat surface perpendicular to the D1 direction. The material of the cover layer 387 may comprise organic carbon. Further, the intermediate structure shown in FIG. 4E may be planarized by a chemical mechanical polishing (CMP) process, for example, the cover layer 387 and the first mask layer 383 are removed until the end surfaces of the second sub-layer 3822 in the first sacrificial layer 382 and the first electrode 310 are exposed.

The manufacturing method 200 proceeds to operation S230. As shown in FIGS. 4F and 4G, the first sacrificial layer 382 may be removed by an etching (e.g., wet etching) process, such that an end portion of the first electrode 310 is exposed. In this way, the end portion of the first electrode 310 protrudes from the stack structure 381.

In some implementations, as shown in FIG. 4H and FIG. 4I, the manufacturing method 200 may further comprise forming a third sacrificial layer 389 on a side of the second sacrificial layer 384-2 in the stack structure 381 in the D1 direction, and making the end portion of the first electrode 310 protruding from the third sacrificial layer 389. Illustratively, the sacrificial material 388 may be deposited on the top side of the intermediate structure shown in FIG. 4G by a thin film deposition process such as CVD, PVD, ALD, or any combination thereof, as shown in FIGS. 4G and 4H. The sacrificial material 388 may cover the end portion of the first electrode 310 protruding from the stack structure 381. For example, the sacrificial material 388 may be the same material (e.g., silicon oxide) as the second sacrificial layer 384-2. Further, as shown in FIG. 4H and FIG. 4I, a portion of the sacrificial material 388 may be removed by an etching (e.g., wet etching and/or dry etching) process, and an end portion of the first electrode 310 is exposed again, and the remaining of the sacrificial material 388 may serve as the third sacrificial layer 389. In other words, the end portion of the first electrode 310 being exposed again may protrude from the third sacrificial layer 389.

It should be noted that the purpose of forming the third sacrificial layer 389 is to reduce the size of the exposed end portion of the first electrode 310 in the D1 direction to meet the design requirements of the thickness (e.g., the size in the D1 direction) of the first insulating layer 320 to be formed subsequently (referring to FIG. 4L). In some implementations, the operation of forming the third sacrificial layer 389 may be omitted by reasonably designing the thickness of the first sacrificial layer 382 (e.g., the size in the D1 direction).

The manufacturing method 200 proceeds to operation S240. As shown in FIGS. 4I-4L, the first insulating layer 320 surrounding at least a portion of the sidewall of the end portion of the first electrode 310 may be formed. For example, the materials of the first insulating layer 320 and the initial second insulating layer 331′ may be the same.

In some implementations, as shown in FIGS. 4I and 4J, the initial first insulating layer 320′ may be formed on a side of the stack structure 381 and the end portion of the first electrode 310 in the D1 direction by a thin film deposition process such as CVD, PVD, ALD, or any combination thereof. Further, as shown in FIG. 4K and FIG. 4L, the pattern for forming the first opening 392 may be transferred to the third mask layer 391 by using the second mask layer 390, and then transferred to the initial first insulating layer 320′, so as to form the first opening 392 extending through the initial first insulating layer 320′. The initial first insulating layer 320′ after forming the first opening 392 is converted into the first insulating layer 320. For example, the second mask layer 390 may be a photoresist. The third mask layer 391 may be a hard mask.

In some implementations, when viewing from the D1 direction, the first opening 392 may be substantially circular, elliptical, rectangular, or other irregular shape. A single first opening 392 may be located between the adjacent first electrodes 310. As an example, the first opening 392 may expose a portion of the first electrode 310 such that the first insulating layer 320 may surround a portion of the sidewall of the end portion of the first electrode 310. As another example, the first opening 392 may not expose the first electrode 310 such that the first insulating layer 320 may surround the entire sidewall of the end portion of the first electrode 310. In addition, since the initial first insulating layer 320′ is formed on a side of the end portion of the first electrode 310 in the D1 direction, then after forming the first opening 392, a portion of the first insulating layer 320 may be located on a side of the end portion of the first electrode 310 in the D1 direction. For example, the materials of the first insulating layer 320 and the second sacrificial layers 384-1, 384-2 are different.

It should be noted that, as shown in FIG. 4J, after the initial first insulating layer 320′ is formed, the planarization process may be performed by a CMP process, for example, such that a surface of the remaining of the initial first insulating layer is coplanar with an end surface of the first electrode 310 (not shown). In this way, after the first opening is formed, the converted first insulating layer may surround at least a portion of the sidewall of the end portion of the first electrode, but not on a side of the end portion of the first electrode in the D1 direction.

In some implementations, as shown in FIGS. 4M-4O, the manufacturing method 200 may further comprise the operation of removing the second sacrificial layers 384-1, 384-2. For example, as shown in FIGS. 4L and 4M, the first opening 392 may expose the second sacrificial layer 384-2. The second sacrificial layer 384-2 may be removed by an etching (e.g., wet etching) process and through the first opening 392. Optionally, in the process of removing the second sacrificial layer 384-2, the third sacrificial layer 389 may also be removed. Further, as shown in FIG. 4M and FIG. 4N, the second opening 393 extending through the initial second insulating layer 331′ may be formed by an etching (e.g., dry etching) process. The second opening 393 may expose the second sacrificial layer 384-1. The initial second insulating layer 331′ after forming the second opening 393 is converted into the second insulating layer 331. Similarly, the second insulating layer 331 may surround at least a portion of the sidewall of the first electrode 310 depending on the size of the second opening 393 in a plane perpendicular to the D1 direction. Further, as shown in FIGS. 4N and 4O, the second sacrificial layer 384-1 may be removed by an etching (e.g., wet etching) process and through the first opening 392 and the second opening 393. For example, the third insulating layer 333 may serve as an etch stop layer for removing the second sacrificial layer 384-1.

It should be noted that, in a case where the number of the second sacrificial layers is greater than 2 and the number of the initial second insulating layers is greater than 1, the operation of forming the second opening extending through the initial second insulating layer and the operation of removing the second sacrificial layer may be alternately performed.

In the above operation, as shown in FIG. 4O, after the second sacrificial layers 384-1 and 384-2 are removed, the first insulating layer 320, the second insulating layer 331 and the third insulating layer 333 may function to support the first electrode 310.

In some implementations, as shown in FIG. 4P, the manufacturing method 200 may further comprise an operation of forming the capacitor C. Illustratively, as shown in FIG. 4O and FIG. 4P, the capacitor dielectric layer 341 may be formed on a side of the first electrode 310 in a direction intersecting with the D1 direction and two opposite sides of the first insulating layer 320 in the D1 direction by a thin film deposition process such as CVD, PVD, ALD, or any combination thereof. Optionally, the capacitor dielectric layer 341 may further be formed on two opposite sides of the second insulating layer 331 in the D1 direction and/or a side of the third insulating layer 333 away from the isolating layer 362 in the D1 direction. Further, the second electrode 342 may be formed on a side of the capacitor dielectric layer 341 away from the first electrode 310 and the first insulating layer 320 by a thin film deposition process such as CVD, PVD, ALD, or any combination thereof. Optionally, the second electrode 342 may also be formed on a side of the capacitor dielectric layer 341 away from at least one of the second insulating layer 331 or the third insulating layer 333. The first electrode 310, the capacitor dielectric layer 341, and the second electrode 342 may be configured to constitute the capacitor C. The conductive layer 343 may be located on a side of the second electrode 342 away from the capacitor dielectric layer 341. The conductive layer 343 may be configured to provide a relatively flat surface perpendicular to the D1 direction. For example, the material of the conductive layer 343 may comprise silicon germanium.

In some implementations, as shown in FIG. 4J, the manufacturing method 200 may further comprise an operation of forming a bit line structure 371. Illustratively, the bit line structure 371 may be formed on surfaces of the interconnected end portions of the semiconductor bodies 351 of a row. As such, the bit line structure 371 may extend along the D2 direction and may be connected to a row of the semiconductor bodies 351 arranged along the D2 direction.

In some implementations, the manufacturing method 200 may further comprise an operation of connecting the peripheral circuit structure (not shown). For example, the peripheral circuit structure may be bonded to a side of the semiconductor body 351 away from the capacitor C in the D1 direction. The peripheral circuit structure may be manufactured in parallel with the intermediate structure of the semiconductor device described above, thereby improving the manufacturing efficiency. Alternatively, the peripheral circuit structure may also be bonded to a side of the capacitor C away from the semiconductor body 351 in the D1 direction.

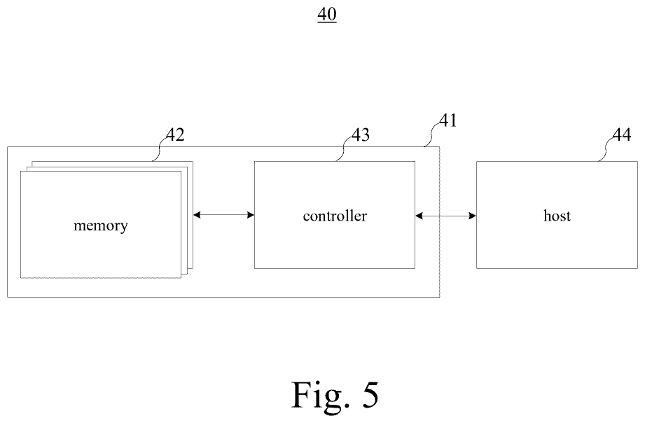

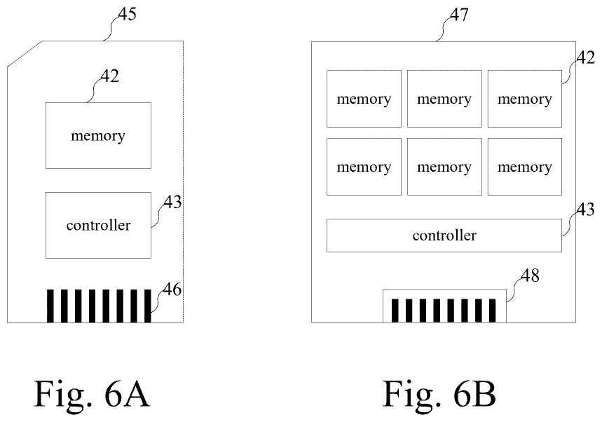

The example of the present disclosure further provides a memory system. FIG. 5 is a schematic block diagram of a system having a memory system provided in an example of the present disclosure. FIG. 6A and FIG. 6B are schematic block diagrams of a memory system provided in an example of the present disclosure.

As shown in FIG. 5, the system 40 may be a mobile phone, a desktop computer, a laptop computer, a tablet, a vehicle computer, a game console, a printer, a positioning device, a wearable electronic device, a smart sensor, a virtual reality (VR) device, an augmented reality (AR) device, or any other suitable electronic device which has a memory system 41 therein. As shown in FIG. 5, the system 40 may comprise a host 44 and the memory system 41 having one or more memories 42 and a controller 43. The host 44 may be a processor of an electronic device, such as a central processing unit (CPU), or may be a system-on-chip (SoC), such as an application processor (AP). The host 44 may be configured to send or receive data to and from the memory 42.

The memory 42 may comprise, for example, the semiconductor device described in any example of the present disclosure. According to some implementations, the controller 43 is coupled to the memory 42 and the host 44 and is configured to control the memory 42. The controller 43 may manage data stored in the memory 42 and communicate with the host 44. In some implementations, the controller 43 is designed to operate in a low duty cycle environment, such as a secure digital (SD) card, compact flash (CF) card, universal serial bus (USB) flash drive, or other medium used in electronic devices such as personal computers, digital cameras, mobile phones, and the like. In some implementations, the controller 43 is designed to operate in a high duty cycle environment, such as an SSD or embedded multi-media-card (eMMC) functioning as a data storage device of a mobile device, such as a smartphone, tablet, laptop, or the like, and an enterprise storage array. The controller 43 may be configured to control operations of the memory 42, such as read, erase, and program operations. The controller 43 may also be configured to manage various functions related to data stored or to be stored in the memory 42, comprising, but not limited to, bad block management, garbage collection, logical-to-physical address translation, wear leveling, and the like. In some implementations, the controller 43 is further configured to process error correction code (ECC) related to data read from or written to the memory 42. Other suitable functions may also be performed by the controller 43, such as formatting the memory 42. The controller 43 may communicate with an external device (e.g., host 44) according to a particular communication protocol. For example, the controller 43 may communicate with external devices through at least one of a variety of interface protocols, such as a USB protocol, an MMC protocol, a Peripheral Component Interconnect (PCI) protocol, a PCI-express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like.

The controller 43 and the one or more memories 42 may be integrated into various types of memory systems, e.g., comprised in the same package, such as a Universal Flash Storage (UFS) package or an eMMC package. That is, the memory system 41 may be implemented and packaged into different types of end electronic products. In one example as shown in FIG. 6A, the controller 43 and the single memory 42 may be integrated into the memory card 45. The memory card 45 may comprise a PC Card (PCMCIA, Personal Computer Memory Card International Association), a CF card, a smart media (SM) card, a memory stick, a multimedia card (MMC, RS-MMC, MMCmicro), an SD card (SD, miniSD, microSD, SDHC), UFS, or the like. The memory card 45 may further comprise a memory card connector 46 that couples the memory card 45 with a host (e.g., the host 44 of FIG. 5). In another example as shown in FIG. 6B, controller 43 and a plurality of memories 42 may be integrated into SSD 47. SSD 47 may further comprise an SSD connector 48 coupling SSD 47 with a host (e.g., host 44 in FIG. 5). In some implementations, the storage capacity and/or operating speed of SSD 47 is higher than that of memory card 45.

In a first aspect, some examples of the present disclosure provide a semiconductor device. The semiconductor device comprises a first electrode and a first insulating layer. The first electrode extends along a first direction and comprises a first end surface, a second end surface, and a sidewall. The first end surface and the second end surface are oppositely arranged in the first direction, and the sidewall connects the first end surface and the second end surface. The first insulating layer surrounds at least a portion of the sidewall of a first end portion of the first electrode and is located on a side of the first end surface away from the second end surface.

In an exemplary implementation, a size of the first electrode in the first direction is greater than 950 nm.

In an exemplary implementation, a ratio of a size of the first electrode in the first direction to a size of the first electrode in a direction intersecting with the first direction is greater than 33.

In an exemplary implementation, a plurality of first electrodes are arranged at intervals; and a portion of the first insulating layer is located on a side of the first end surface of each first electrode away from the second end surface.

In an exemplary implementation, the first insulating layer is in contact with at least a portion of the sidewall of the first end portion and is in contact with the first end surface.

In an exemplary implementation, the first insulating layer comprises a first extension portion and a second extension portion. The first extension portion surrounds at least a portion of the sidewall of the first end portion, the second extension portion is located on a side of the first end surface away from the second end surface, wherein the first extension portion and the second extension portion are coplanar on a surface away from the first end surface in the first direction.

In an exemplary implementation, a material of the first insulating layer comprises at least one of silicon nitride, silicon carbonitride, and silicon boron nitride.

In an exemplary implementation, the semiconductor device further comprises a second electrode and a capacitor dielectric layer. A portion of the second electrode is located on a side of the first electrode in a direction intersecting with the first direction, a portion of the second electrode is located on two opposite sides of the first insulating layer in the first direction, and a portion of the capacitor dielectric layer is located between the first electrode and the second electrode.

In an exemplary implementation, the semiconductor device further comprises a second insulating layer. The second insulating layer has a spacing distance from the first insulating layer in the first direction and surrounds at least a portion of the sidewall of the first electrode, wherein the portion of the second electrode is located on two opposite sides of the second insulating layer in the first direction.

In an exemplary implementation, the portion of the capacitor dielectric layer and the portion of the second electrode extend through the first insulating layer and the second insulating layer along the first direction.

In an exemplary implementation, the semiconductor device further comprises a semiconductor body. The semiconductor body extends along the first direction. The semiconductor device is located on a side of the first electrode in the first direction and away from the first end surface.

In an exemplary implementation, the semiconductor device further comprises a gate structure and a gate dielectric layer. The gate structure is located on at least one side of the semiconductor body in a direction intersecting with the first direction, and the gate dielectric layer is located between the semiconductor body and the gate structure.

In an exemplary implementation, the semiconductor device further comprises a connecting structure. The connecting structure extends along the first direction and is connected to the second end surface and the semiconductor body.

In a second aspect, some examples of the present disclosure provide a memory system. The memory system comprises a memory and a controller, and the memory comprises the semiconductor device according to any one of the implementations mentioned above. The controller is coupled to the memory and configured to control the memory to store data.

In a third aspect, some examples of the present disclosure provide a manufacturing method of a semiconductor device. The manufacturing method of the semiconductor device comprises:
forming a hole extending through a first sacrificial layer and a stack structure along a first direction, wherein the first sacrificial layer is located on a side of the stack structure in the first direction; forming a first electrode in the hole; removing the first sacrificial layer, wherein an end portion of the first electrode protrudes from the stack structure; and forming a first insulating layer surrounding at least a portion of a sidewall of the end portion.

In an exemplary implementation, forming the first insulating layer surrounding at least a portion of the sidewall of the end portion comprises: forming an initial first insulating layer on a side of the stack structure and the end portion in the first direction; forming a first opening extending through the initial first insulating layer to obtain the first insulating layer, wherein a remaining portion of the first insulating layer is located on a side of the end portion in the first direction.

In an exemplary implementation, the stack structure comprises a second sacrificial layer and an initial second insulating layer alternately disposed in the first direction, and the first opening exposes the second sacrificial layer, wherein the manufacturing method further comprises: forming a second opening extending through the initial second insulating layer to obtain a second insulating layer; and removing the second sacrificial layer via at least one of the first opening or the second opening

In an exemplary implementation, materials of the first insulating layer and the second insulating layer are the same, and materials of at least portions of the first sacrificial layer, the second sacrificial layer and the first insulating layer are different from each other.

In an exemplary implementation, the manufacturing method further comprises: forming a capacitor dielectric layer on a side of the first electrode in a direction intersecting with the first direction and two opposite sides of the first insulating layer in the first direction; and forming a second electrode on a side of the capacitor dielectric layer away from the first electrode and the first insulating layer.

In an exemplary implementation, after removing the first sacrificial layer, the manufacturing method further comprises: forming a third sacrificial layer on a side of the second sacrificial layer in the first direction, and protruding the end portion from the third sacrificial layer. For example, a material of the third sacrificial layer is the same as the material of the second sacrificial layer.

In an exemplary implementation, the manufacturing method further comprises:
forming a semiconductor body extending along the first direction, wherein the stack structure is formed on a side of the semiconductor body in the first direction; forming a gate structure on at least one side of the semiconductor body in a direction intersecting with the first direction; and forming a gate dielectric layer between the gate structure and the semiconductor body.

The above description is only an illustration of the implementations of the present disclosure and its application principles. Those skilled in the art should understand that the protection scope involved in the present disclosure is not limited to the technical solutions constituted by the specific combination of the technical features described above, but also cover other technical solutions formed by any combination of the above technical features or their equivalent features without departing from the technical concept, for example, the technical solutions formed by replacing the above features with the technical features having similar functions disclosed (but not limited to) in the present disclosure.

What is claimed is:

1. A semiconductor device, comprising:
a first electrode extending along a first direction and comprising a first end surface, a second end surface, and a first sidewall, wherein the first end surface and the second end surface are oppositely arranged in the first direction, and the first sidewall connects the first end surface with the second end surface; and
a first insulating layer surrounding at least a portion of a second sidewall of a first end portion of the first electrode and located on a side of the first end surface away from the second end surface.

2. The semiconductor device of claim 1, wherein a size of the first electrode in the first direction is greater than 950 nm.

3. The semiconductor device of claim 1, wherein a ratio of a size of the first electrode in the first direction to a size of the first electrode in a direction intersecting with the first direction is greater than 33.

4. The semiconductor device of claim 1, wherein the first electrode comprises a plurality of first electrodes that are arranged at intervals; and a portion of the first insulating layer is located on a side of the first end surface of respective first electrode away from the second end surface.

5. The semiconductor device of claim 1, wherein the first insulating layer is in contact with the at least the portion of the second sidewall of the first end portion and is in contact with the first end surface.

6. The semiconductor device of claim 1, wherein the first insulating layer comprises:
a first extension portion surrounding the at least the portion of the second sidewall of the first end portion; and
a second extension portion located on a side of the first end surface away from the second end surface;
wherein the first extension portion and the second extension portion are coplanar on a surface away from the first end surface in the first direction.

7. The semiconductor device of any one of claim 1, wherein a material of the first insulating layer comprises at least one of silicon nitride, silicon carbonitride, or silicon boron nitride.

8. The semiconductor device of any one of claim 1, further comprising:
a second electrode, wherein a first portion of the second electrode is located on a side of the first electrode in a direction intersecting with the first direction, and a second portion of the second electrode is located on two opposite sides of the first insulating layer in the first direction; and
a capacitor dielectric layer, wherein a portion of the capacitor dielectric layer is located between the first electrode and the second electrode.

9. The semiconductor device of claim 8, further comprising:
a second insulating layer having a spacing distance to the first insulating layer in the first direction and surrounding at least a portion of the first sidewall of the first electrode;
wherein the portion of the second electrode is located on two opposite sides of the second insulating layer in the first direction.

10. The semiconductor device of claim 9, wherein the portion of the capacitor dielectric layer and the portion of the second electrode extend through the first insulating layer and the second insulating layer along the first direction.

11. The semiconductor device of claim 1, further comprising:
a semiconductor body extending along the first direction and located on a side of the first electrode in the first direction and away from the first end surface.

12. The semiconductor device of claim 11, further comprising:
a gate structure located on at least one side of the semiconductor body in a direction intersecting with the first direction; and
a gate dielectric layer located between the semiconductor body and the gate structure.

13. The semiconductor device of claim 11, further comprising:
a connecting structure extending along the first direction and connected to the second end surface and the semiconductor body.

14. A memory system, comprising:
a memory, comprising:
a semiconductor device, comprising:
a first electrode extending along a first direction and comprising a first end surface, a second end surface, and a first sidewall, wherein the first end surface and the second end surface are oppositely arranged in the first direction, and the first sidewall connects the first end surface with the second end surface; and
a first insulating layer surrounding at least a portion of a second sidewall of a first end portion of the first electrode and located on a side of the first end surface away from the second end surface; and
a controller coupled to the memory and configured to control the memory to store data.

15. A manufacturing method of a semiconductor device, the manufacturing method comprising:
forming a hole extending through a first sacrificial layer and a stack structure along a first direction, wherein the first sacrificial layer is located on a side of the stack structure in the first direction;
forming a first electrode in the hole;
removing the first sacrificial layer, wherein an end portion of the first electrode protrudes from the stack structure; and
forming a first insulating layer surrounding at least a portion of a sidewall of the end portion.

16. The manufacturing method of claim 15, wherein forming the first insulating layer surrounding the at least the portion of the sidewall of the end portion comprises:
forming an initial first insulating layer on the side of the stack structure and the end portion in the first direction; and
forming a first opening extending through the initial first insulating layer to obtain the first insulating layer, wherein a remaining portion of the initial first insulating layer is located on a side of the end portion in the first direction.

17. The manufacturing method of claim 16, wherein the stack structure comprises a second sacrificial layer and an initial second insulating layer alternately disposed in the first direction, and the first opening exposes the second sacrificial layer;
wherein the manufacturing method further comprises:
forming a second opening extending through the initial second insulating layer to obtain the second insulating layer; and
removing the second sacrificial layer via at least one of the first opening or the second opening.

18. The manufacturing method of claim 17, wherein materials of the first insulating layer and the second insulating layer are the same, and materials of at least portions of the first sacrificial layer, the second sacrificial layer and the first insulating layer are different from each other.

19. The manufacturing method of claim 17, further comprising:
forming a capacitor dielectric layer on a side of the first electrode in a direction intersecting with the first direction and two opposite sides of the first insulating layer in the first direction; and
forming a second electrode on a side of the capacitor dielectric layer away from the first electrode and the first insulating layer.

20. The manufacturing method of claim 17, wherein after removing the first sacrificial layer, the manufacturing method further comprises:
forming a third sacrificial layer on a side of the second sacrificial layer in the first direction, and making the end portion protruding from the third sacrificial layer.
